(19) United States
(12) Patent Application Publication
(10) Pub. No.: US 2026/0173464 A1
(43) Pub. Date: Jun. 18, 2026

(54) SEMICONDUCTOR DEVICE AND METHOD OF MANUFACTURING SEMICONDUCTOR DEVICE

(71) Applicant: FUJI ELECTRIC CO., LTD., Kawasaki-shi (JP)

(72) Inventor: Tomohiro MORIYA, Matsumoto-city (JP)

(73) Assignee: FUJI ELECTRIC CO., LTD., Kawasaki-shi (JP)

(21) Appl. No.: 19/376,624

(22) Filed: Oct. 31, 2025

(30) Foreign Application Priority Data
Dec. 17, 2024 (JP) 2024-221203

(51) Int. Cl. H10D 62/10; H10D 30/01; H10D 30/66; H10D 62/00; H10D 62/832

(52) U.S. Cl. CPC H10D 62/111; H10D 30/0291; H10D 30/665; H10D 62/054; H10D 62/8325

(57) ABSTRACT

A semiconductor device, including: a semiconductor substrate; a first semiconductor layer provided on the semiconductor substrate; a second semiconductor layer provided on the first semiconductor layer; a first parallel pn structure and a second parallel pn structure provided in the second semiconductor layer, respectively in the active region and the termination structure portion; a plurality of second semiconductor regions, each provided in one of the first semiconductor regions in the active region; and a plurality of gate electrodes provided via gate insulating films in the active region. The first parallel pn structure includes first column regions and second column regions repeatedly alternating each other. The second parallel pn structure includes third column regions and fourth column regions repeatedly alternating each other. A column length of the second parallel pn structure is longer than that of the first parallel pn structure.

### CROSS REFERENCE TO RELATED APPLICATIONS

This application is based upon and claims the benefit of priority of the prior Japanese Patent Application No. 2024-221203, filed on Dec. 17, 2024, the entire contents of which are incorporated herein by reference.

### BACKGROUND OF THE INVENTION

### 1. Field of the Invention

Embodiments of the invention relate to semiconductor device and a method of manufacturing a semiconductor device.

### 2. Description of the Related Art

Conventionally, a semiconductor device in which a thickness of a parallel pn layer of an active portion is thinner than a thickness of a pn layer of a voltage withstanding structure portion, and a p⁺-type outer peripheral region is provided between the parallel pn layer of the active portion and a p-type base region is commonly known (for example, refer to Japanese Laid-Open Patent Publication No. 2023-139377).

### SUMMARY OF THE INVENTION

According to an embodiment of the present disclosure, a semiconductor device includes: a semiconductor substrate of a first conductivity type, having an active region and a termination structure portion surrounding a periphery of the active region in a plan view of the semiconductor device; a first semiconductor layer of the first conductivity type, provided at a surface of the semiconductor substrate, the first semiconductor layer having a dopant concentration that is lower than a dopant concentration of the semiconductor substrate, the first semiconductor layer having a first surface and a second surface opposite to each other, the second surface facing the semiconductor substrate; a second semiconductor layer of the first conductivity type, provided at the first surface of the first semiconductor layer, and having a first portion in the termination structure portion and a second portion in the active region, the first portion being thicker than the second portion, the second semiconductor layer having a dopant concentration that is higher than the dopant concentration of the first semiconductor layer, and having a first surface and a second surface opposite to each other, the second surface of the second semiconductor layer facing the first semiconductor layer; a first parallel pn structure provided in the second semiconductor layer and in the active region, the first parallel pn structure having a first surface and a second surface opposite to each other, the second surface facing the semiconductor substrate, the first parallel pn structure including a plurality of first column regions of the first conductivity type and a plurality of second column regions of a second conductivity type that are disposed repeatedly alternating each other in a direction parallel to the surface of the semiconductor substrate; a plurality of first semiconductor regions of the second conductivity type, provided in the first parallel pn structure, at the first surface of the first parallel pn structure, in the active region, each of the plurality of first semiconductor regions having a first surface and a second surface opposite to each other, the second surface facing the semiconductor substrate; a plurality of second semiconductor regions of the first conductivity type, each provided in one of the plurality of first semiconductor regions at the first surface thereof in the active region; a plurality of gate insulating films each in contact with a portion of one of the plurality of first semiconductor regions and a portion of one of the plurality of second semiconductor regions, in the active region; a plurality of gate electrodes provided via the plurality of gate insulating films, in the active region; and a second parallel pn structure provided in the second semiconductor layer and in the termination structure portion, the second parallel pn structure including a plurality of third column regions of the first conductivity type and a plurality of fourth column regions of the second conductivity type that are disposed repeatedly alternating each other in the direction parallel to the surface of the semiconductor substrate. The second parallel pn structure has a column length that is longer than a column length of the first parallel pn structure.

Objects, features, and advantages of the present invention are specifically set forth in or will become apparent from the following detailed description of the invention when read in conjunction with the accompanying drawings.

### BRIEF DESCRIPTION OF THE DRAWINGS

FIG. 1 is a cross-sectional view of a structure of a silicon carbide semiconductor device according to an embodiment, along cutting line X-X′ depicted in FIG. 2.

FIG. 2 is a top view of the structure of the silicon carbide semiconductor device according to the embodiment.

FIG. 3 is a cross-sectional view of another structure of the silicon carbide semiconductor device, according to the embodiment along cutting line X-X′ depicted in FIG. 2.

FIG. 4 is a flowchart of a method of manufacturing the semiconductor device according to the embodiment.

FIG. 5 is a cross-sectional view depicting the method of manufacturing the silicon carbide semiconductor device according to the embodiment.

FIG. 6 is a cross-sectional view depicting the method of manufacturing the silicon carbide semiconductor device according to the embodiment.

FIG. 7 is a cross-sectional view depicting the method of manufacturing the silicon carbide semiconductor device according to the embodiment.

FIG. 8 is a cross-sectional view depicting the method of manufacturing the silicon carbide semiconductor device according to the embodiment.

FIG. 9 is a cross-sectional view depicting the method of manufacturing the silicon carbide semiconductor device according to the embodiment.

FIG. 10 is a cross-sectional view depicting the method of manufacturing the silicon carbide semiconductor device according to the embodiment.

FIG. 11 is a cross-sectional view of a structure of a conventional silicon carbide semiconductor device, along cutting line X-X′ depicted in FIG. 12.

FIG. 12 is a top view of the structure of the conventional silicon carbide semiconductor device.

### DETAILED DESCRIPTION OF THE INVENTION

First, problems associated with the conventional techniques are discussed. A conventional semiconductor device has a problem in that increasing breakdown voltage of an edge portion is difficult. The present disclosure relates to a semiconductor device and a method of manufacturing a semiconductor device that enable the breakdown voltage of the edge portion to be made higher than the breakdown voltage of an active portion.

An outline of an embodiment of the present disclosure is described. A semiconductor device according to the present disclosure solving the problems above has the following features. A semiconductor substrate of a first conductivity type, has an active region and a termination structure portion provided outside the active region, surrounding a periphery of the active region; a first semiconductor layer of the first conductivity type, is provided at a surface of the semiconductor substrate, the first semiconductor layer having a dopant concentration that is lower than a dopant concentration of the semiconductor substrate, the first semiconductor layer having a first surface and a second surface opposite to each other, the second surface facing the semiconductor substrate. A second semiconductor layer of the first conductivity type, is provided at the first surface of the first semiconductor layer and has a dopant concentration that is higher than the dopant concentration of the first semiconductor layer, the second semiconductor layer having a first surface and a second surface opposite to each other, the second surface of the second semiconductor layer facing the first semiconductor layer. A first parallel pn structure in which a plurality of first column regions of the first conductivity type and a plurality of second column regions of a second conductivity type are disposed repeatedly alternating each other in a direction parallel to the surface of the semiconductor substrate, is provided in the second semiconductor layer, in the active region, the first parallel pn structure having a first surface and a second surface opposite to each other, the second surface facing the semiconductor substrate. A plurality of first semiconductor regions of the second conductivity type, is provided in the first parallel pn structure, at the first surface of the first parallel pn structure, in the active region, each of the plurality of first semiconductor regions. A plurality of second semiconductor regions of the first conductivity type, each is selectively provided in a corresponding one of the plurality of first semiconductor regions, at the first surface of the corresponding one of the plurality of first semiconductor regions, in the active region. A plurality of gate insulating films, each is in contact with a portion of the plurality of first semiconductor regions and a portion of the plurality of second semiconductor regions, in the active region; and a plurality of gate electrodes is provided via the plurality of gate insulating films, in the active region. A second parallel pn structure in which a plurality of third column regions of the first conductivity type and plurality of fourth column regions of the second conductivity type are disposed repeatedly alternating each other in the direction parallel to the surface of the semiconductor substrate, is provided in the second semiconductor layer, in the termination structure portion. The second semiconductor layer has a first portion in the termination structure portion and a second portion in the active region, the first portion being thicker than the second portion, and the second parallel pn structure has a column length that is longer than a column length of the first parallel pn structure.

According to the disclosure above, the column length of the second parallel pn layer of the edge termination region is longer than the column length of the first parallel pn layer of the active region. As a result, the breakdown voltage of the edge termination region may be made higher than the breakdown voltage of the active region. When avalanche breakdown occurs, avalanche current is distributed in the active region, which has a large area, and thus, destruction of the semiconductor device may be suppressed.

Further, in the semiconductor device according to the present disclosure, in the disclosure above, the second parallel pn structure has a first surface and a second surface opposite to each other, the second surface facing the semiconductor substrate, and the first surface of the second parallel pn structure is farther from the semiconductor substrate than is the first surface of the first parallel pn structure.

Further, in the semiconductor device according to the present disclosure, in the disclosure above, the plurality of first semiconductor regions, the plurality of second semiconductor regions, the plurality of gate insulating films, and the plurality of gate electrodes are provided closer to the semiconductor substrate than is the first surface of the second semiconductor layer in the termination structure portion.

Further, in the semiconductor device according to the present disclosure, in the disclosure above, a third semiconductor region of the second conductivity type, is provided in the second parallel pn structure, at a first surface thereof opposite to a second surface thereof facing the semiconductor substrate, the third semiconductor region being provided in the termination structure portion. The second semiconductor layer has a first portion in the active region, a second portion in the termination structure portion, and a third portion in the termination structure portion, the second portion being thicker than first portion and the third portion having a same thickness as a thickness of the first portion. The third semiconductor region is provided in the second portion and the third portion of the second semiconductor layer.

Further, in the semiconductor device according to the present disclosure, in the disclosure above, one of the plurality of fourth column regions of the second parallel pn structure is in contact with one of the plurality of first column regions of the first parallel pn structure.

A method of manufacturing a semiconductor device according to the present disclosure solving the above problems has the following features. A semiconductor substrate of a first conductivity type and having an active region and a termination structure portion provided outside the active region, surrounding a periphery of the active region, is prepared; and forming a first semiconductor layer of the first conductivity type is formed at a surface of the semiconductor substrate, the first semiconductor layer having a dopant concentration that is lower than a dopant concentration of the semiconductor substrate. Next, a second semiconductor layer of the first conductivity type is formed at a surface of the first semiconductor layer, the second semiconductor layer having a dopant concentration that is higher than the dopant concentration of the first semiconductor layer. Next, a first parallel pn structure in which a plurality of first column regions of the first conductivity type and a plurality of second column regions of a second conductivity type are disposed repeatedly alternating each other in a direction parallel to the surface of the semiconductor substrate, is formed in the second semiconductor layer, in the active region, and a second parallel pn structure in which a plurality of third column regions of the first conductivity type and plurality of fourth column regions of the second conductivity type are disposed repeatedly alternating each other in the direction parallel to the surface of the semiconductor substrate, is formed in the second semiconductor layer, in the termination structure portion. Next, the surface of the second semiconductor layer where the first parallel pn structure is formed is etched and recessed. Next, a plurality of first semiconductor regions of the second conductivity type is formed in the second semiconductor layer, at the recessed surface thereof. Next, a plurality of second semiconductor regions of the first conductivity type is selectively formed in the second semiconductor layer, at the recessed surface thereof. Next, a plurality of gate insulating films in contact with a portion of the plurality of first semiconductor regions and a portion of the plurality of second semiconductor regions is formed; and a plurality of gate electrodes is formed via the plurality of insulating films. The second parallel pn structure is formed having a column length that is longer than a column length of the first parallel pn structure.

Findings underlying the present disclosure are discussed. Conventionally, one commonly known semiconductor device has a super junction (SJ) structure in which the drift layer is a parallel pn layer formed by adjacent n-type regions and p-type regions disposed repeatedly alternating each other in a direction parallel to a main surface of the substrate. The n-type regions and the p-type regions configuring the parallel pn layer extend linearly, parallel to a main surface of a semiconductor substrate (semiconductor chip). The n-type regions and the p-type regions configuring the parallel pn layer are provided substantially uniformly in substantially an entire area of the semiconductor substrate, from the active region of a center (chip center) of the semiconductor substrate to an end of the semiconductor substrate (chip end).

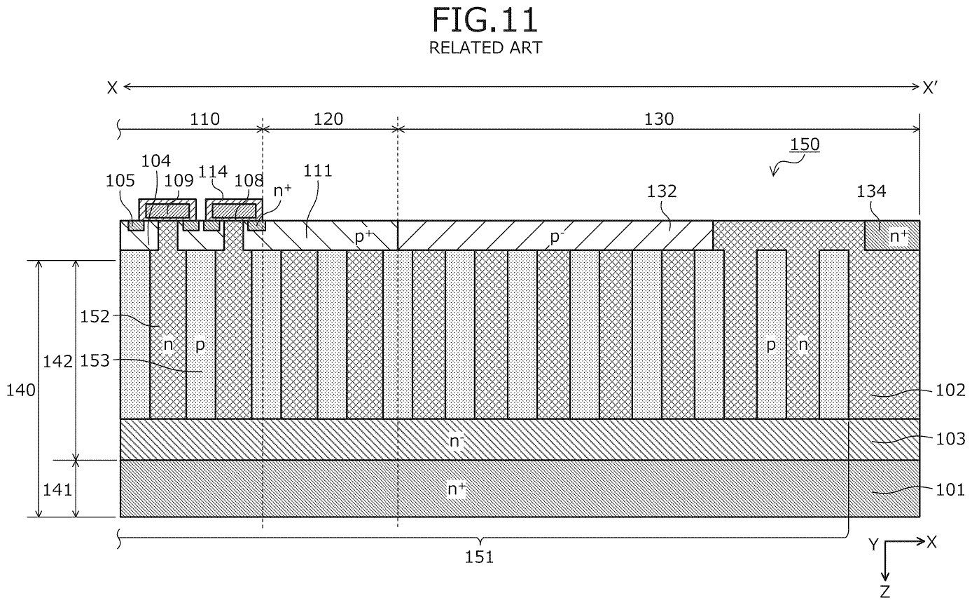

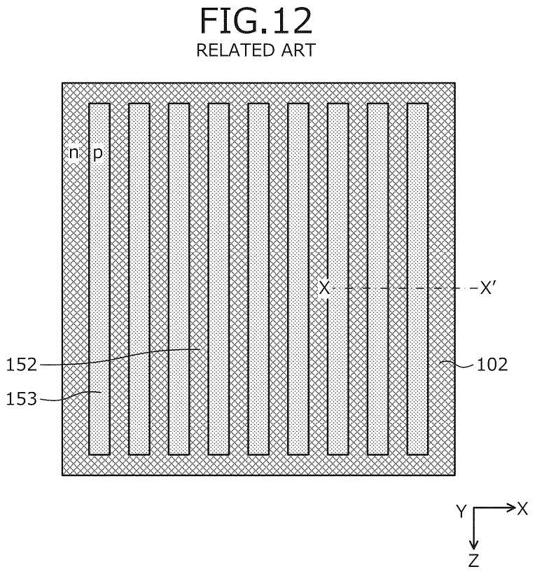

A structure of a conventional silicon carbide semiconductor device having an SJ structure is described taking a metal oxide semiconductor field effect transistor (MOSFET) having insulated gates with a three-layer metal-oxide-semiconductor structure is described as an example. FIG. 11 is a cross-sectional view of the structure of the conventional silicon carbide semiconductor device, along cutting line X-X′ depicted in FIG. 12. FIG. 12 is a top view of the structure of the conventional silicon carbide semiconductor device.

A conventional silicon carbide semiconductor device 150 depicted in FIGS. 11 and 12 has a general planar gate structure in an active region 110 of a semiconductor substrate (semiconductor chip) 140 containing silicon carbide and is a vertical MOSFET having a SJ structure in which an n-type drift layer 102 is a parallel pn layer 151. The semiconductor substrate 140 has a substantially rectangular shape in a plan view. The active region 110 has a substantially rectangular shape in a plan view and is provided in a center (chip center) of the semiconductor substrate 140. A periphery of the active region 110 is surrounded by an edge termination region 130 via an intermediate region 120, in a plan view.

The semiconductor substrate 140 is formed by stacking an n-type epitaxial layer 142 constituting an n⁻-type buffer layer 103 and the n-type drift layer 102 on an n⁺-type starting substrate 141 containing silicon carbide. The semiconductor substrate 140 has, as a front surface, a main surface having the n-type epitaxial layer 142 and, as a back surface, a main surface having the n⁺-type starting substrate 141, which constitutes an n⁺-type drain region 101. The n-type epitaxial layer 142 is a portion constituting the n-type drift layer (drift region) 102 and includes the parallel pn layer 151.

Above a front surface of the n⁺-type starting substrate 141 (surface facing the n-type drift layer 102), a MOS gate structure configured by p⁺-type base regions 104, n⁺-type source regions 105, gate insulating films 108, and gate electrodes 109 is provided. The gate electrodes 109 are electrically insulated from a source electrode (not depicted) by an interlayer insulating film 114. In the intermediate region 120, a p⁺-type region 111 extends to a later-described JTE structure 132, from sidewalls of the p⁺-type base regions 104, the sidewalls that face the edge termination region 130.

In the intermediate region 120, a gate wiring layer (not depicted) such as a gate finger is disposed. The edge termination region 130 is a region between the intermediate region 120 and an end of the semiconductor substrate 140 (chip end). In the edge termination region 130, a junction termination extension (JTE) structure 132 and an n⁺-type channel stopper region 134 are disposed as a voltage withstanding structure. The JTE structure 132 surrounds the periphery of the active region 110 via the intermediate region 120 in a plan view.

The n⁺-type channel stopper region 134 is disposed closer to the chip end than is the JTE structure 132, is apart from the JTE structure 132, and reaches the end of the semiconductor substrate 140. The n⁺-type channel stopper region 134 extends along the end of the semiconductor substrate 140, surrounding a periphery of the JTE structure 132 in a plan view.

The parallel pn layer 151 is provided uniformly in substantially an entire area of the semiconductor substrate 140, from the active region 110 to the edge termination region 130. The parallel pn layer 151 is a SJ structure in which adjacent n-type regions 152 and p-type regions 153 are disposed repeatedly alternating each other in a first direction X that is parallel to the front surface of the semiconductor substrate 140. The n-type regions 152 and the p-type regions 153 of the parallel pn layer 151 extend linearly in a second direction Y that is parallel to the front surface of the semiconductor substrate 140 and orthogonal to the first direction X.

The n-type regions 152 and the p-type regions 153 of the parallel pn layer 151 are disposed in substantially an entire area of the edge termination region 130, from directly below (side facing the n⁺-type drain region 101) the JTE structure 132. The parallel pn layer 151 is in contact with the JTE structure 132 and does not reach the front surface of the semiconductor substrate 140 between the JTE structure 132 and the n⁺-type channel stopper region 134.

The n-type regions 152 and the p-type regions 153 of the parallel pn layer 151 are disposed at equal intervals in substantially an entire area of the semiconductor substrate 140, from the active region 110 to the edge termination region 130. Respective carrier concentrations (dopant concentrations) and widths (widths in the first direction X) of the n-type regions 152 and the p-type regions 153 of the parallel pn layer 151 are set so that the charge of any one of the n-type regions 152 and the charge of an adjacent one of the p-type regions 153 of the parallel pn layer 151 are balanced.

The charge being balanced means that an amount of charge represented by a product of the carrier concentration and the width of one the n-type regions 152 and an amount of charge represented by a product of the carrier concentration and the width of one of the p-type regions 153 are substantially the same within a range that includes an allowable error due to process variation.

As depicted in FIG. 11, in the silicon carbide semiconductor device 150, a SJ structure in which the parallel pn layer 151 having the n-type regions 152 and the p-type regions 153 of the same column length is used in the active region 110 and in the edge termination region 130. In the SJ structure, a depletion layer spreads in a horizontal direction of the parallel pn layer 151, which is arranged orthogonally with respect to the semiconductor substrate 140 and thus, a thickness of the depletion layer is equivalent to the column length of the SJ structure.

In the silicon carbide semiconductor device 150, when avalanche breakdown occurs, avalanche current may be distributed by causing avalanche breakdown to occur in the active region 110, which has a relatively large area, whereby destruction of the silicon carbide semiconductor device 150 may be suppressed. Thus, the breakdown voltage of the edge termination region 130 is made higher than the breakdown voltage of the active region 110.

However, in the SJ structure, the breakdown voltage is mainly determined by the column length of the SJ structure and thus, when the column length of the SJ structure is the same in the active region 110 and the edge termination region 130, a problem arises in that making the breakdown voltage of the edge termination region 130 higher than the breakdown voltage of the active region 110 is difficult.

Embodiments of a silicon carbide semiconductor device and a method of manufacturing a silicon carbide semiconductor device according to the present disclosure solving the problems of the conventional silicon carbide semiconductor device above are described in detail with reference to the accompanying drawings. In the present description and accompanying drawings, layers and regions prefixed with n or p mean that majority carriers are electrons or holes. Additionally, + or − appended to n or p means that the dopant concentration is higher or lower, respectively, than layers and regions without + or −. In the description of the embodiments below and the accompanying drawings, main portions that are identical are given the same reference numerals and are not repeatedly described. Further, with consideration of variation in manufacturing, description indicating the same or equal may be within 5%.

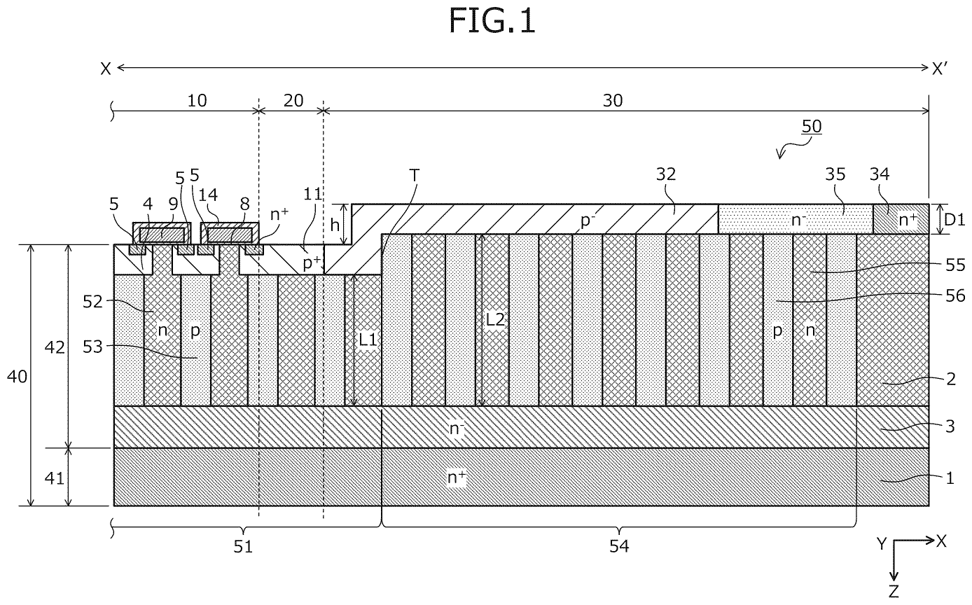

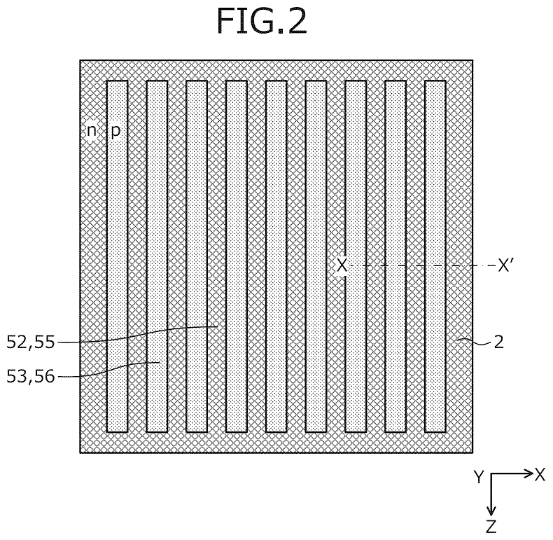

A structure of a silicon carbide semiconductor device according to an embodiment is described taking a MOSFET as an example. FIG. 1 is a cross-sectional view of the structure of the silicon carbide semiconductor device according to the embodiment, along cutting line X-X′ depicted in FIG. 2. FIG. 2 is a top view of the structure of the silicon carbide semiconductor device according to the embodiment. In FIG. 2, the number of n-type regions 52 (first column regions) and p-type regions 53 (second column regions) of a first parallel pn layer 51 is simplified and differs from that depicted in FIG. 1.

A silicon carbide semiconductor device 50 according to the embodiment has a semiconductor substrate (semiconductor chip) 40 that contains silicon carbide (SiC) and has an active region 10, an intermediate region 20, and an edge termination region (termination structure portion) 30; the silicon carbide semiconductor device 50 is a vertical MOSFET with a planar gate structure (device structure) having a SJ structure in which an n-type drift layer (second semiconductor layer of the first conductivity type) 2, from the active region 10 to the edge termination region 30, is a parallel pn layer (a first parallel pn layer 51, a second parallel pn layer 54). The active region 10 is a region through which a main current passes when the MOSFET is in an on-state and is disposed in a center of the semiconductor substrate 40 (chip center).

The intermediate region 20 is adjacent to the active region 10 and surrounds a periphery of the active region 10, in a plan view. The edge termination region 30 is a region between the intermediate region 20 and an end of the semiconductor substrate 40 and surrounds the periphery of the active region 10 via the intermediate region 20.

A boundary between the active region 10 and the intermediate region 20 is an outer end (end facing the edge termination region 30) of a later-described interlayer insulating film 14. A boundary between the intermediate region 20 and the edge termination region 30 is an inner peripheral end (inner periphery) of a later-described JTE structure 32. The inner peripheral end of the JTE structure 32 is an inner peripheral end of an innermost p-type region of multiple p-type regions configuring the JTE structure 32 and is connected to (forms an interface) with a later-described p⁺-type region 11 of the intermediate region 20.

The edge termination region 30 is region between the active region 10 and the end of the semiconductor substrate 40, and surrounds a periphery of the intermediate region 20, in a plan view. In the active region 10 and the intermediate region 20, the n-type drift layer 2 is a SJ structure configured by the first parallel pn layer 51. In the edge termination region 30, the SJ structure is configured by the second parallel pn layer 54, which is formed by the first parallel pn layer 51 and the n-type drift layer 2.

As depicted in FIG. 1, in the silicon carbide semiconductor device 50 according to the embodiment, in the active region 10, a general planar gate structure is provided in the semiconductor substrate 40, at a front surface thereof. The planar gate structure is configured by p⁺-type base regions (first semiconductor regions of a second conductivity type) 4, n⁺-type source regions (second semiconductor regions of the first conductivity type) 5, gate insulating films 8, and gate electrodes 9. Further, p⁺⁺-type contact regions (not depicted) may be provided. The semiconductor substrate 40 is formed by stacking an n-type epitaxial layer 42 constituting the n-type drift layer 2 on a front surface of an n⁺-type starting substrate (semiconductor substrate of the first conductivity type) 41 containing silicon carbide.

The semiconductor substrate 40 has, as the front surface, a main surface having the n-type epitaxial layer 42 and as a back surface (second main surface), a main surface having the n⁺-type starting substrate 41. The n⁺-type starting substrate 41 constitutes an n⁺-type drain region 1. In the embodiment, between the n⁺-type drain region 1 and the parallel pn layer (the first parallel pn layer 51, the second parallel pn layer 54) is a semi-SJ structure in which an n—type buffer layer (first semiconductor layer of the first conductivity type) 3 is provided. Portions of each of the p⁺-type base regions 4 are sandwiched between the n-type drift layer 2 and the n⁺-type source regions 5; at surfaces of said portions, the gate insulating films 8 are provided so as to extend to regions between the p⁺-type base regions 4 that are adjacent to each other (so-called JFET region). The gate insulating films 8 may be provided on the n-type drift layer 2 and the n⁺-type source regions 5. On the gate insulating films 8, the gate electrodes 9 are provided. The gate electrodes 9 are electrically insulated from a source electrode (not depicted) by the interlayer insulating film 14.

The p⁺-type base regions 4 extend linearly in a second direction Y. The n⁺-type source regions 5 are selectively provided at the surfaces of the p⁺-type base regions 4, respectively. The p⁺⁺-type contact regions may be selectively provided at the surfaces of the p⁺-type base regions 4. In the active region 10, in a portion thereof closest to the edge termination region 30, the p⁺-type region 11 extends to the later-described JTE structure 32, from a sidewall of an outermost one of the p⁺-type base regions 4, the sidewall closest to the edge termination region 30.

The edge termination region 30 has a function of relaxing electric field toward the front surface (first main surface) of the semiconductor substrate 40, in the n-type drift layer 2 in the active region 10 and the intermediate region 20, thereby sustaining the breakdown voltage. The breakdown voltage is voltage limit at which leakage current does not increase excessively and no malfunction or destruction of the device occurs. In the edge termination region 30, as a voltage withstanding structure, the junction termination extension (JTE) structure 32 and an n⁺-type channel stopper region 34 are disposed. The JTE structure 32 surrounds the periphery of the active region 10 via the intermediate region 20 in a plan view.

The JTE structure (third semiconductor region of the second conductivity type) 32 is a structure in which multiple p-type regions are disposed in concentric shapes surrounding, in a plan view, the periphery of the active region 10 via the intermediate region 20, the multiple p-type regions being disposed in descending order of dopant concentration in a direction from the active region 10 to the chip end. The JTE structure 32 may mitigate the concentration of electric field closer to the chip end than is the intermediate region 20 and prevent device destruction due to application of a voltage less than a predetermined voltage (the breakdown voltage of the edge termination region 30). Instead of the JTE structure 32, a guard ring may be provided.

The n⁺-type channel stopper region 34 is disposed apart from the JTE structure 32 and closer to the chip end than is the JTE structure 32, for example, at the four edges (linear portions) of the end of the semiconductor substrate 40, the n⁺-type channel stopper 34 reaches the end of the semiconductor substrate 40. The n⁺-type channel stopper 34 extends along the end of the semiconductor substrate 40 and surrounds the periphery of the JTE structure 32 in a plan view.

The first parallel pn layer (first parallel pn structure) 51 is a SJ structure in which the n-type regions (first column regions of the first conductivity type) 52 and the p-type regions (second column regions of the second conductivity type) 53 are disposed adjacent to and repeatedly alternating each other in the first direction X parallel to the front surface of the semiconductor substrate 40. The n-type regions 52 and the p-type regions 53 of the first parallel pn layer 51 extend linearly to a vicinity of the end of the edge termination region 30, in the second direction Y, which is parallel to the front surface of the semiconductor substrate 40 and orthogonal to the first direction X. Further, the first parallel pn layer 51 is disposed in the first direction X, in the active region 10, the intermediate region 20, and the edge termination region 30. Thus, a boundary between the first parallel pn layer 51 and the second parallel pn layer 54 is positioned in the edge termination region 30.

In the first parallel pn layer 51, the charge of any one of the n-type regions 52 and the charge of an adjacent one of the p-type regions 53 are roughly balanced. The charge being balanced means that an amount of charge represented by a product of the carrier concentration (dopant concentration) and the width of one of the n-type regions of the parallel pn layer and an amount of charge represented by a product of the carrier concentration and the width of one of the p-type regions are substantially the same within a range that includes an allowable error due to process variation. Accordingly, the respective carrier concentrations and widths (widths in the first direction X) of the n-type regions 52 and the p-type regions 53 are set so that the charge of any one of the n-type regions 52 and an adjacent one of the p-type regions 53 of the first parallel pn layer 51 are generally balanced.

The charge of any one of the n-type regions 52 and an adjacent one of the p-type regions 53 of the first parallel pn layer 51 suffice to be roughly balanced and the respective carrier concentrations and widths of the n-type regions 52 and the p-type regions 53 of the first parallel pn layer 51 are suitably set. For example, the width of each of the n-type regions 52 of the first parallel pn layer 51 and the width of each of the p-type regions 53 may be substantially the same. In this instance, the carrier concentration of the n-type regions 52 and the carrier concentration of the p-type regions 53 may be set to be substantially the same. The widths being substantially the same and the carrier concentrations being substantially the same means that each are within a corresponding range that includes an allowable error due to process variation.

The second parallel pn layer (second parallel pn structure) 54 is a SJ structure in which n-type regions (third column regions of the first conductivity type) 55 and p-type regions (fourth column regions of the second conductivity type) 56 are disposed repeatedly alternating each other in the first direction X parallel to the front surface of the semiconductor substrate 40. The n-type regions 55 and the p-type regions 56 of the second parallel pn layer 54 are parallel to the n-type regions 52 and the p-type regions 53 of the first parallel pn layer 51 and extend linearly in the second direction Y. The second parallel pn layer 54 is connected to both sides of the first parallel pn layer 51 of the active region 10 in the second direction Y and is disposed in the edge termination region 30. The second parallel pn layer 54 is connected to both sides of the first parallel pn layer 51 in the first direction X and is disposed in the edge termination region 30. The second parallel pn layer 54 is disposed so that in the first direction X, p-type regions 56 are adjacent to outermost ones of the n-type regions 52 of the first parallel pn layer 51 in the first direction X. Further, the second parallel pn layer 54 is disposed closer to the chip end than is outer peripheral end (outer periphery) of the JTE structure 32 in the first direction X, so that at least one of the p-type regions 56 is disposed closer to the chip end in the first direction X than is the outer peripheral end of the JTE structure 32.

One or more of the p-type regions 56 of the second parallel pn layer 54 is disposed closer to the chip end in the first direction X than is the outer peripheral end of the JTE structure 32, whereby a concentration of electric field at the outer peripheral end of the JTE structure 32 may be suppressed when the MOSFET is off. The outer peripheral end of the JTE structure 32 is an outer peripheral end of an outermost one of the multiple p-type regions configuring the JTE structure 32.

The range in which the second parallel pn layer 54 is disposed is set within the above-mentioned range from the outer peripheral end of the JTE structure 32 in the first direction X, and the number of floating p-type regions 56 disposed in the edge termination region 30 is reduced. As a result, the amount of accumulated charge of minority carriers (holes) that accumulate in the edge termination region 30 due to MOSFET switching, etc., and remain without being discharged to the outside may be reduced. Thus, preferably, the number of the p-type regions 56 disposed outside the outer peripheral end of the JTE structure 32 in the first direction X may be small.

Provided that the second parallel pn layer 54 is within the above-mentioned range from the outer peripheral end of the JTE structure 32 in the first direction X, the first parallel pn layer 51 may be provided in the first direction X, to directly below the n⁺-type channel stopper 34 (the side thereof facing the n⁺-type drain region 1). Between the second parallel pn layer 54 and the end of the semiconductor substrate 40 in the first direction X, a normal n-type drift region 2 may be disposed. The size of the semiconductor substrate 40 may be reduced by omitting the normal n-type drift region 2 or by reducing a width of the normal n-type drift region 2.

The n-type regions 55 and the p-type regions 56 of the second parallel pn layer 54 are in contact with the JTE structure 32, in a depth direction Z. The p-type regions 56 of the second parallel pn layer 54 provided closer to the chip end than is the JTE structure 32 are provided at a depth D1 from the surface of the semiconductor substrate 40 and are not exposed at the surface of the semiconductor substrate 40. The depth D1, for example, is a same as a thickness of the JTE structure 32. Between the surface of the semiconductor substrate 40 and a portion of the second parallel pn layer 54 provided closer to the chip end than is the JTE structure 32, an n⁻-type layer 35 having a dopant concentration lower than that of the normal n-type drift region 2 is disposed. As a result, spreading of a depletion layer in a direction to the chip end is facilitated.

In the second parallel pn layer 54, the charge of any one of the n-type regions 55 and the charge of an adjacent one of the p-type regions 56 are roughly balanced. In the second parallel pn layer 54, the respective carrier concentrations and widths (widths in the first direction X) of the n-type regions 55 and the p-type regions 56 are set so that the charge of any one of the n-type regions 55 and the charge of an adjacent one of the p-type regions 56 are roughly balanced. The charge of any one of the n-type regions 55 and the charge of an adjacent one of the p-type regions 56 suffice to be roughly balanced and the respective carrier concentrations and widths of the n-type regions 55 and the p-type regions 56 of the second parallel pn layer 54 are suitably set. For example, in the second parallel pn layer 54, the width of each of the n-type regions 55 and the width of each of the p-type regions 56 may be substantially the same. In this instance, the carrier concentration of the n-type regions 55 and the carrier concentration of the p-type regions 56 suffice to be set to be substantially the same.

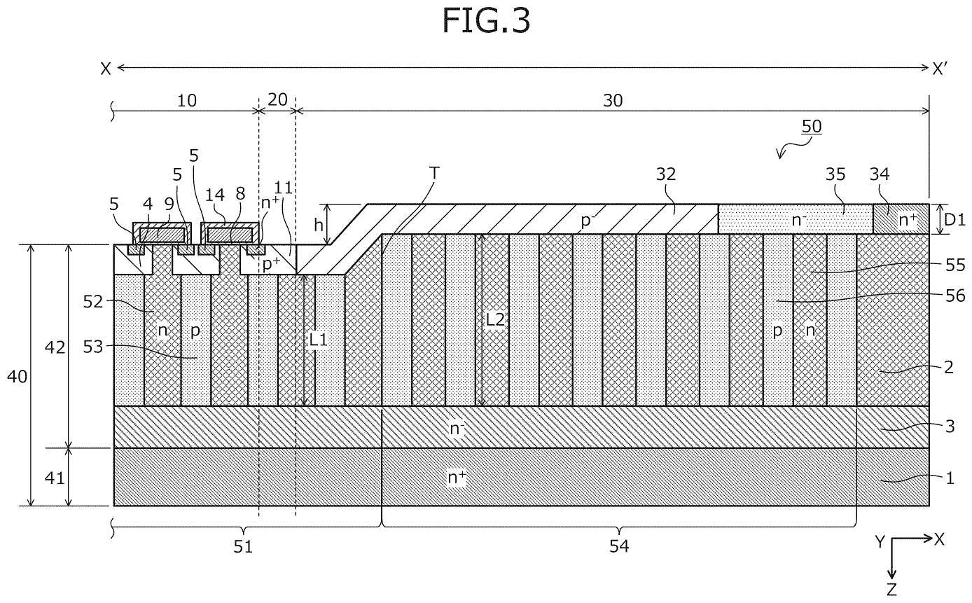

In the embodiment, the thickness of the semiconductor substrate 40 is reduced in an entire area of the active region 10 and the intermediate region 20 and a portion of the edge termination region 30, from the surfaces thereof by an amount, height h, in a direction to the n⁺-type drain region 1. A step T, for example, is vertical as depicted in FIG. 1. FIG. 3 is a cross-sectional view of another structure of the silicon carbide semiconductor device, according to the embodiment along cutting line X-X′ depicted in FIG. 2. As depicted in FIG. 3, the step T may be sloped. Further, preferably, the location of the step T may be at one of the p-type regions 56. In other words, an innermost one of the p-type regions 56 of the second parallel pn layer 54 is in contact with an outermost one of the n-type regions 52 of the first parallel pn layer 51. As a result, concentration of electric field at corner portions of the p-type regions 56, which have a relatively high dopant concentration, and decreases in the breakdown voltage may be prevented.

As described, the thickness of the semiconductor substrate 40 is reduced in the entire area of the active region 10 and the intermediate region 20 and in a portion of the edge termination region 30 by the height h from the respective surfaces thereof and thus, in the SJ structure, the column length (lengths of the n-type regions 55 and the p-type regions 56) of the second parallel pn layer 54 of the edge termination region 30 is longer than the column length (lengths of the n-type regions 52 and the p-type regions 53) of the first parallel pn layer 51 of the active region 10. The n-type regions 55 and the p-type regions 56 are provided from a front surface of the n⁻-type buffer layer 3 to a surface of the n⁻-type layer 35 or the JTE structure 32, said surface facing the n⁺-type drain region 1 while the n-type regions 52 and the p-type regions 53 are provided from the front surface of the n⁻-type buffer layer 3 to surfaces of the p⁺-type base regions 4 or a surface of the p⁺-type region 11, said surface(s) facing the n⁺-type drain region 1. Thus, the second parallel pn layer 54 of the edge termination region 30, on the side thereof opposite to the side facing the n⁺-type drain region, is longer than the first parallel pn layer 51 of the active region 10.

As depicted in FIGS. 1 and 3, a column length L2 of the second parallel pn layer 54 is longer than a column length L1 of the first parallel pn layer 51 (L2>L1). Further, preferably, this difference in length (L2−L1) may be in a range of 10% to 25% of the column length L1 and more preferably, may be in a range of 15% to 20% thereof. When the difference is less than 10%, an effect of the embodiment decreases and when greater than 25%, on-resistance increases and fabrication cost increases.

The breakdown voltage of the SJ structure is determined by the column length of the SJ structure and thus, the column length of the edge termination region 30 is made longer than the column length of the active region 10, whereby the breakdown voltage of the edge termination region 30 may be made higher than the breakdown voltage of the active region 10. As described, when avalanche breakdown occurs, avalanche current is distributed in the active region 10, which has a large area, and thus, destruction of the silicon carbide semiconductor device may be suppressed.

The n⁻-type buffer layer 3 is provided between the first parallel pn layer 51 and the n⁺-type drain region 1 in the active region 10. On the semiconductor substrate (the n⁺-type drain region 1) side, the n⁻-type buffer layer 3 may suppress a depletion layer that spreads below the SJ structure. Further, in the edge termination region 30 as well, the n⁻-type buffer layer 3 is provided between the second parallel pn layer 54 and the n⁺-type drain region 1.

As depicted in FIGS. 1 and 3, in the edge termination region 30, of the p-type regions 53, an innermost one closest to the intermediate region 20 is partially provided toward the intermediate region 20. Thus, the innermost one of the p-type regions 53 is in contact with both the p⁺-type region 11 and the JTE structure 32. For example, each of the innermost ones of the p-type regions 53 may be provided so that substantially a center thereof is between the intermediate region 20 and the edge termination region 30.

Further, as depicted in FIGS. 1 and 3, at the outer peripheral ends of the JTE structure 32 in the first direction X and the second direction Y, while the JTE structure 32 is in contact with the p-type regions 56, the JTE structure 32 may be structured to be in contact with the n-type regions 55.

Further, as depicted in FIGS. 1 and 3, the JTE structure 32 is further provided in a region of the semiconductor substrate 40 where the thickness is reduced by the height h. In other words, in the edge termination region 30, a region of the semiconductor substrate 40 has the same thickness as that of the active region 10 and a region of the semiconductor substrate 40 has a thickness that is relatively thinner by the height h; and the JTE structure 32 is provided in both the region having the same thickness and the region having the relatively thinner thickness. The JTE structure 32 being provided in the region having the relatively thinner thickness, enables relaxation of the electric field of the edge termination region 30, whereby the breakdown voltage may be increased.

Further, in the active region 10, the semiconductor substrate 40 is thinner by the height h and thus, the p⁺-type region 11, the gate electrodes 9, the gate insulating films 8, the n⁺-type source regions 5, and the p⁺-type base regions 4 provided in the active region 10 are provided closer to the n⁺-type drain region 1 than is the front surface of the semiconductor substrate 40 in the edge termination region 30. As described, the gate structure is formed at a location that is lower than the edge termination region 30 and thus, adhesion of the source electrode and/or a protective film provided on the source electrode is improved.

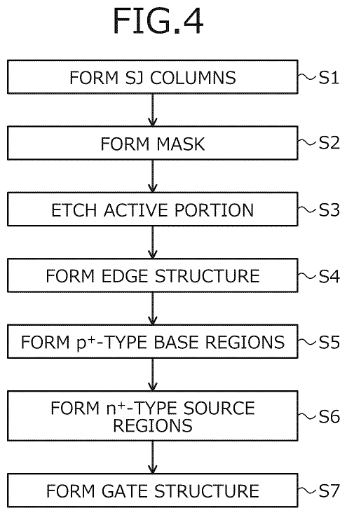

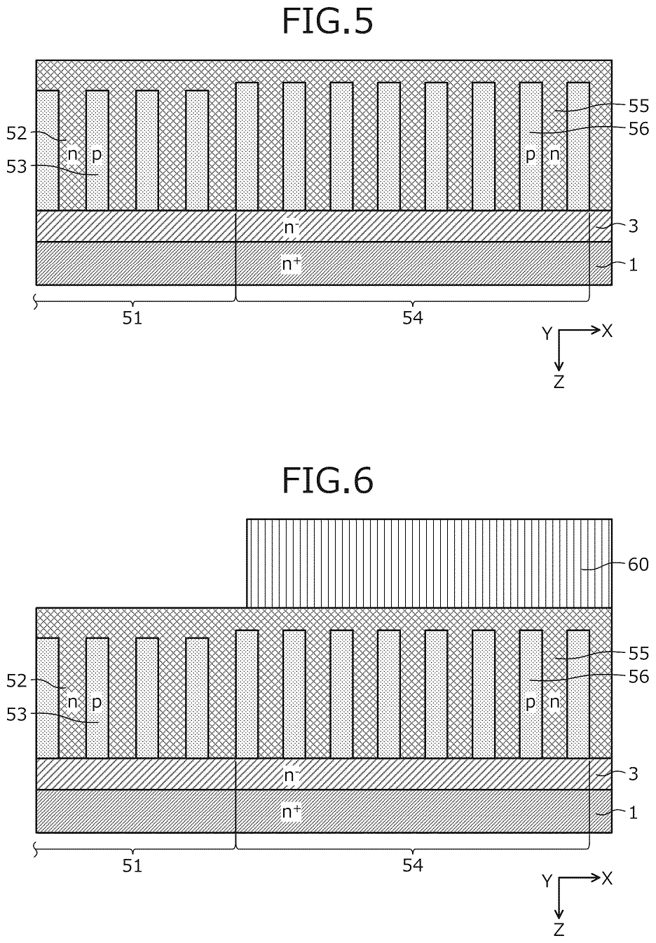

Next, a method of manufacturing the silicon carbide semiconductor device 50 according to the embodiment is described. FIG. 4 is a flowchart of the method of manufacturing the semiconductor device according to the embodiment. FIGS. 5, 6, 7, 8, 9, and 10 are cross-sectional views depicting the method of manufacturing the silicon carbide semiconductor device according to the embodiment.

First, at the front surface of the n⁺-type starting substrate (semiconductor wafer) 41 constituting the n⁺-type drain region 1, the n⁻-type buffer layer 3 and the n-type drift layer 2 including the first parallel pn layer 51 and the second parallel pn layer 54 are formed (step S1: first process to third process). The state up to here is depicted in FIG. 5. For example, when a multi-stage epitaxial method is used, on the n⁻-type buffer layer 3, epitaxial growth of the n-type epitaxial layer 42 constituting the n-type drift layer 2 is divided into multiple sessions (for example, 9 stages) and in each stage of epitaxial growth, ion implantation is performed so that in the n-type epitaxial layer 42, regions of the same conductivity type are in contact with each other in a depth direction Z, whereby regions constituting the n-type regions 52, 55 and the p-type regions 53, 56 are selectively formed. For example, after the last stage or second to last stage of the growth of the n-type epitaxial layer 42 constituting the n⁻-type buffer layer 3, the implantation of p-type ions is not performed in the portion where the semiconductor substrate 40 is to be recessed, whereby the second parallel pn layer 54 of the column length of the edge termination region 30 may be made longer than the column length of the first parallel pn layer 51 of the active region 10. In the implantation of p-type ions, for example, the acceleration energy is varied between 60 keV to 700 keV and the ion implantation is performed multiple times so that an average dopant concentration of aluminum in one stage of the p-type regions 53, 56 exhibits a box profile of 9.0×10¹⁶/cm³. A process of epitaxial growth by a multi-stage epitaxial method and multi-stage ion implantation is repeatedly performed multiple times and thus, even when each stage of the p-type regions 53, 56 exhibits a box profile, with regard to concentration distribution in the depth direction, a cross-section of each of the p-type regions 53, 56 exhibits one peak and two bottoms. The p-type regions 53, 56 each having a cross-section exhibiting one peak and two bottoms at each stage exhibit periodic distribution in the depth direction in which the p-type regions 53, 56 are connected. The connected portions of the p-type regions 53 and the p⁺-type base regions 4, preferably, may penetrate in the depth direction from portions where the concentration of the p-type regions 53 exhibits a bottom.

Further, for example, after the n-type epitaxial layer 42 constituting the n⁻-type buffer layer 3 and the n-type drift layer 2 is formed, the first parallel pn layer 51 and the second parallel pn layer 54 may be formed using a trench embedding epitaxial method of forming trenches (hereinafter, SJ trenches) in the n-type epitaxial layer 42 so as to leave portions constituting the n-type regions 52, 55, and embedding the SJ trenches with a p-type epitaxial layer to form the p-type regions 53, 56. For example, the length of the SJ trenches in the portion recessed toward the n⁺-type starting substrate 41 is shorter than the length thereof in other portions, whereby the column length of the second parallel pn layer 54 of the edge termination region 30 may be longer than the column length of the first parallel pn layer 51 of the active region 10.

Next, a mask 60 opened at a portion to be recessed toward the n⁺-type drain region 1 is formed (step S2). The state up to here is depicted in FIG. 6. For example, the mask 60 is formed using an oxide film mask.

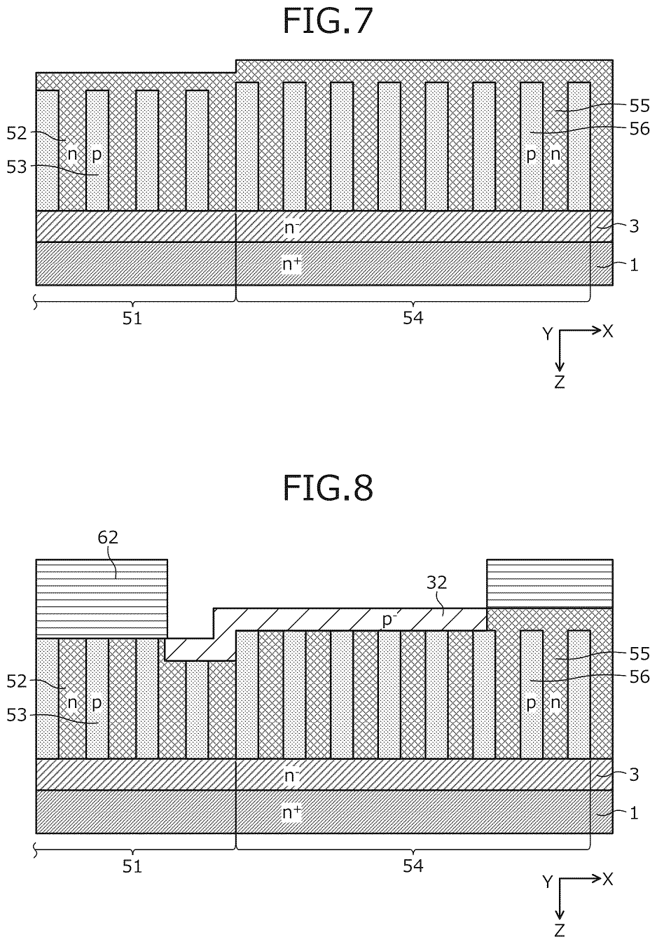

Next, the front surface of the semiconductor substrate 40 is etched (step S3: fourth process). The etching may be dry etching or wet etching. Thus, the entire surface of the active region 10 and the intermediate region 20 and a portion of the edge termination region 30 is recessed toward the n⁺-type drain region 1. The state up to here is depicted in FIG. 7.

Next, an edge structure is formed (step S4). For example, a resist 62 having an opening at a region where the JTE structure 32 is to be formed is formed and by ion implantation of a p-type dopant, the JTE structure 32 is formed in the semiconductor substrate 40, at the front surface thereof. The state up to here is depicted in FIG. 8. Similarly, the resist 62 is removed, the resist 62 having an opening at a region where the n⁺-type channel stopper region 34 is to be formed is newly formed and by ion implantation of an n-type dopant, the n⁺-type channel stopper region 34 is formed in the semiconductor substrate 40, at the front surface thereof. Similarly, the resist 62 is removed, the resist 62 having an opening at a region where the n⁻-type layer 35 is to be formed is newly formed and by ion implantation of an n-type dopant, the n⁻-type layer 35 is formed in the semiconductor substrate 40, at the front surface thereof. Next, the resist 62 is removed.

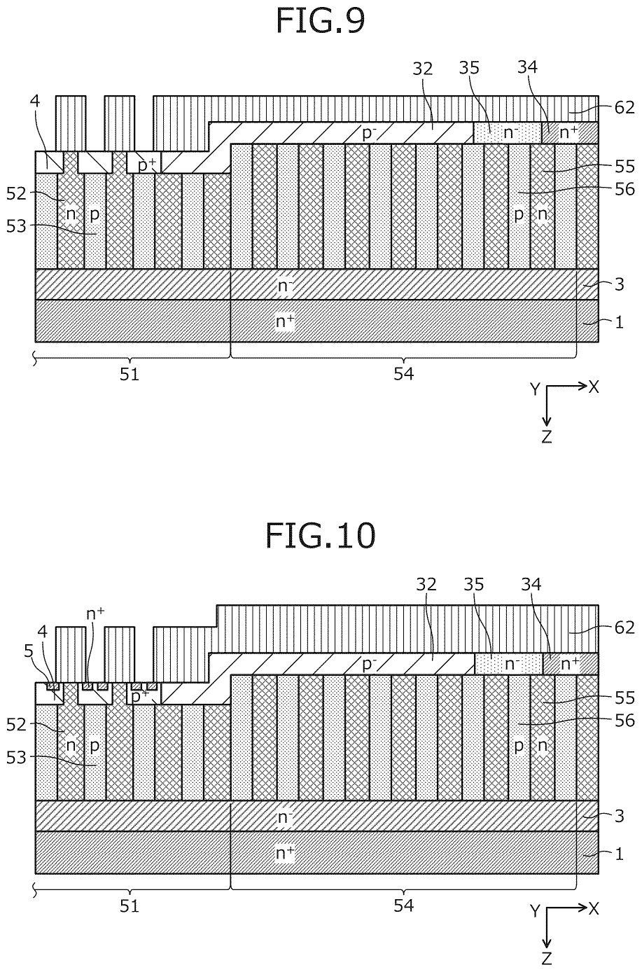

Next, the p⁺-type base regions 4 are formed (step S5: fifth process). For example, the resist 62 having openings where the p⁺-type base regions 4 are to be formed is formed and by ion implantation of a p-type dopant, the p⁺-type base regions 4 are formed in the semiconductor substrate 40, at the front surface thereof. The p⁺-type region 11 of the intermediate region 20 is formed simultaneously. The state up to here is depicted in FIG. 9. Next, the resist 62 is removed.

Next, the n⁺-type source regions 5 are formed (step S6: sixth process). For example, the resist 62 having openings where the n⁺-type source regions 5 are to be formed is formed and by ion implantation of an n-type dopant, the n⁺-type source regions 5 are formed in the semiconductor substrate 40, at the front surface. The state up to here is depicted in FIG. 10. Next, the resist 62 is removed. Next, a heat treatment (annealing) for activating the p⁺-type base regions 4 and the n⁺-type source regions 5 is performed. Further, a sequence in which the p⁺-type base regions 4 and the n⁺-type source regions 5 are formed may be variously changed.

Next, the gate structure is formed (step S7: seventh process). For example, next, the front surface of the semiconductor substrate 40 is thermally oxidized, thereby forming the gate insulating film 8. Next, on the gate insulating film 8, as the gate electrodes 9, for example, a polycrystal silicon layer doped with phosphorus is formed. Next, the polycrystal silicon layer is patterned and selectively removed, leaving the polycrystal silicon layer on portions sandwiched by the n⁺-type source regions 5 of the p⁺-type base regions 4 and the n-type regions 52. Here, the polycrystal silicon layer may be left on the n-type regions.

Next, for example, a phosphosilicate glass (PSG) is deposited as the interlayer insulating film 14 so as to cover the gate electrodes 9. Next, the interlayer insulating film 14 and the gate insulating film 8 are patterned and selectively removed. For example, portions of the interlayer insulating film 14 and the gate insulating film 8 are removed from above the n⁺-type source regions 5, thereby forming contact holes and exposing the n⁺-type source regions 5. Next, a heat treatment (reflow) for planarizing the interlayer insulating film 14 is performed.

Next, the source electrode (not depicted) is deposited by sputtering and is patterned by photolithography and etching. At this time, the source electrode is embedded in the contact holes, whereby the n⁺-type source regions 5 and the source electrode are electrically connected to each other. In the contact holes, tungsten plugs or the like may be embedded via a barrier metal.

Next, for example, a nickel film is deposited as a drain electrode (not depicted), at a surface (back surface of the semiconductor wafer) of the semiconductor substrate 40. Subsequently, a heat treatment is performed, forming an ohmic junction between the semiconductor substrate 40 and the drain electrode. Thus, the silicon carbide semiconductor device depicted in FIG. 1 is completed.

As described above, according to the embodiment, the column length of the second parallel pn layer of the edge termination region is longer than the column length of the first parallel pn layer of the active region. As a result, the breakdown voltage of the edge termination region may be made higher than the breakdown voltage of the active region. When avalanche breakdown occurs, avalanche current is distributed in the active region, which has a large area, and thus, destruction of the silicon carbide semiconductor device may be suppressed.

In the foregoing, in the present disclosure, while an instance in which a MOS gate structure is configured at a first main surface of a silicon carbide substrate is described as an example, without limitation hereto, various modifications such as with regard to the surface orientation of a main surface of the substrate are possible. Further, in the embodiments of the present disclosure, while a planar MOSFET is described as an example, without limitation hereto, the present disclosure is applicable to semiconductor devices of various types of configurations such as MOS-type semiconductor devices like trench-type MOSFETs, planar IGBTs, and trench-type IGBTs. Further, in the embodiments described above, while an instance in which silicon carbide is used as a semiconductor is described as an example, a semiconductor other than silicon carbide is applicable such as, for example, silicon (Si) and gallium nitride (GaN). Further, in the present disclosure, in the embodiments, while the first conductivity type is assumed to be an n-type and the second conductivity type is assumed to be a p-type, the present disclosure is similarly implemented when the first conductivity type is a p-type and the second conductivity type is an n-type.

According to the disclosure above, the column length of the second parallel pn layer of the edge termination region is longer than the column length of the first parallel pn layer of the active region. As a result, the breakdown voltage of the edge termination region may be made higher than the breakdown voltage of the active region. When avalanche breakdown occurs, avalanche current is distributed in the active region, which has a large area and thus, destruction of the semiconductor device may be suppressed.

The semiconductor device according to the present disclosure and the method of manufacturing a semiconductor device achieve an effect in that the breakdown voltage of the edge portion may be made higher than the breakdown voltage of the active portion.

As described, the silicon carbide semiconductor device according to the present disclosure is useful for high voltage semiconductor devices such as those used in power converting equipment, power source devices of, for example, various types of industrial machines, and the like.

Although the invention has been described with respect to a specific embodiment for a complete and clear disclosure, the appended claims are not to be thus limited but are to be construed as embodying all modifications and alternative constructions that may occur to one skilled in the art which fairly fall within the basic teaching herein set forth.

What is claimed is:

1. A semiconductor device, comprising:
a semiconductor substrate of a first conductivity type, having an active region and a termination structure portion surrounding a periphery of the active region in a plan view of the semiconductor device;
a first semiconductor layer of the first conductivity type, provided at a surface of the semiconductor substrate, the first semiconductor layer having a dopant concentration that is lower than a dopant concentration of the semiconductor substrate, the first semiconductor layer having a first surface and a second surface opposite to each other, the second surface facing the semiconductor substrate;
a second semiconductor layer of the first conductivity type, provided at the first surface of the first semiconductor layer, and having a first portion in the termination structure portion and a second portion in the active region, the first portion being thicker than the second portion, the second semiconductor layer having a dopant concentration that is higher than the dopant concentration of the first semiconductor layer, and having a first surface and a second surface opposite to each other, the second surface of the second semiconductor layer facing the first semiconductor layer;
a first parallel pn structure provided in the second semiconductor layer and in the active region, the first parallel pn structure having a first surface and a second surface opposite to each other, the second surface facing the semiconductor substrate, the first parallel pn structure including a plurality of first column regions of the first conductivity type and a plurality of second column regions of a second conductivity type that are disposed repeatedly alternating each other in a direction parallel to the surface of the semiconductor substrate;
a plurality of first semiconductor regions of the second conductivity type, provided in the first parallel pn structure, at the first surface of the first parallel pn structure, in the active region, each of the plurality of first semiconductor regions having a first surface and a second surface opposite to each other, the second surface facing the semiconductor substrate;
a plurality of second semiconductor regions of the first conductivity type, each provided in one of the plurality of first semiconductor regions at the first surface thereof in the active region;
a plurality of gate insulating films each in contact with a portion of one of the plurality of first semiconductor regions and a portion of one of the plurality of second semiconductor regions, in the active region;
a plurality of gate electrodes provided via the plurality of gate insulating films, in the active region; and
a second parallel pn structure provided in the second semiconductor layer and in the termination structure portion, the second parallel pn structure including a plurality of third column regions of the first conductivity type and a plurality of fourth column regions of the second conductivity type that are disposed repeatedly alternating each other in the direction parallel to the surface of the semiconductor substrate, wherein
the second parallel pn structure has a column length that is longer than a column length of the first parallel pn structure.

2. The semiconductor device according to claim 1, wherein
the second parallel pn structure has a first surface and a second surface opposite to each other, the second surface facing the semiconductor substrate, and
the first surface of the second parallel pn structure is farther from the semiconductor substrate than is the first surface of the first parallel pn structure.

3. The semiconductor device according to claim 1, wherein
the plurality of first semiconductor regions, the plurality of second semiconductor regions, the plurality of gate insulating films, and the plurality of gate electrodes are provided closer to the semiconductor substrate than is the first surface of the second semiconductor layer in the termination structure portion.

4. The semiconductor device according to claim 1, wherein
the second parallel pn structure has a first surface and a second surface opposite to each other, the second surface facing the semiconductor substrate,
the semiconductor device further includes a third semiconductor region of the second conductivity type, provided in the second parallel pn structure at the first surface thereof, and in the termination structure portion,
the second semiconductor layer further has a third portion in the termination structure portion, the third portion being thinner than first portion and having a same thickness as a thickness of the second portion, and
the third semiconductor region is provided in the first portion and the third portion of the second semiconductor layer.

5. The semiconductor device according to claim 1, wherein
one of the plurality of fourth column regions of the second parallel pn structure is in contact with one of the plurality of first column regions of the first parallel pn structure.

6. A method of manufacturing the semiconductor device, the method comprising:
preparing a semiconductor substrate of a first conductivity type, the semiconductor substrate having an active region and a termination structure portion surrounding a periphery of the active region in a plan view of the semiconductor device;
forming a first semiconductor layer of the first conductivity type at a surface of the semiconductor substrate, the first semiconductor layer having a dopant concentration that is lower than a dopant concentration of the semiconductor substrate;
forming a second semiconductor layer of the first conductivity type at a surface of the first semiconductor layer, the second semiconductor layer having a dopant concentration that is higher than the dopant concentration of the first semiconductor layer;
forming, in the second semiconductor layer, a first parallel pn structure in the active region, and a second parallel pn structure in the termination structure portion, the first parallel pn structure including a plurality of first column regions of the first conductivity type and a plurality of second column regions of a second conductivity type that are disposed repeatedly alternating each other in a direction parallel to the surface of the semiconductor substrate, the second parallel pn structure including a plurality of third column regions of the first conductivity type and plurality of fourth column regions of the second conductivity type that are disposed repeatedly alternating each other in the direction parallel to the surface of the semiconductor substrate, a column length of the second parallel pn structure being longer than that of the first parallel pn structure;
etching and recessing the surface of the second semiconductor layer where the first parallel pn structure is formed;
forming a plurality of first semiconductor regions of the second conductivity type in the second semiconductor layer, at the recessed surface thereof;
selectively forming a plurality of second semiconductor regions of the first conductivity type in the second semiconductor layer, at the recessed surface thereof;
forming a plurality of gate insulating films each in contact with a portion of one of the plurality of first semiconductor regions and a portion of one of the plurality of second semiconductor regions; and
forming a plurality of gate electrodes via the plurality of insulating films, respectively.
